(19) United States
(12) Patent Application Publication
(10) Pub. No.: US 2026/0361299 A1
(43) Pub. Date: Nov. 12, 2026

(54) VOLTAGE SELECTOR CIRCUIT

(71) Applicant: Silicon Integrated Systems Corp., HSINCHU CITY (TW)

(72) Inventors: Song sheng LIN, HSINCHU CITY (TW); Keng-nan CHEN, HSINCHU CITY (TW); Cheng-yi Huang, Hsinchu City (TW)

(21) Appl. No.: 19/449,870

(22) Filed: Jan. 15, 2026

(30) Foreign Application Priority Data
Mar. 13, 2025 (TW) 114109406

(51) Int. Cl. H03K 17/10; H03K 19/20

(52) U.S. Cl. CPC H03K 17/102; H03K 19/20

(57) ABSTRACT

This application provides a voltage selector circuit, which controls a first P-type transistor and a second P-type transistor to be turned on or off respectively to output a first voltage or a second voltage as a maximum voltage at a voltage output node. Special requirements of threshold voltages of the first P-type transistor and the second P-type transistor are not required in the voltage selector circuit. In case of high load current, the voltage outputted by the voltage output node will not have a voltage drop by the threshold voltage, and the first voltage or the second voltage can be accurately outputted as the maximum voltage.

### CROSS-REFERENCE TO RELATED APPLICATIONS

This application claims the priority of Taiwan Patent Application No. 114109406, filed on Mar. 13, 2025, the disclosure of which is incorporated herein by reference in its entirety.

### TECHNICAL FIELD OF DISCLOSURE

This application relates to the field of electronic circuits, and more particularly to a voltage selection circuit.

### BACKGROUND OF DISCLOSURE

In some electronic applications, multiple power supply options can be provided to power a circuit. For example, a voltage selector typically includes two or more selectable power supply voltage points. One supply voltage can be chosen from several available power supply voltages. In some cases, it is necessary to determine which available voltage is the highest and use the highest voltage as an output.

FIG. 1 shows a conventional voltage selector circuit. The voltage selection circuit includes a first P-type transistor M1 and a second P-type transistor M2 which can be P-type metal-oxide-semiconductor field-effect transistors (PMOS). Input terminals (e.g., sources) of the first P-type transistor M1 and the second P-type transistor M2 are respectively connected to a first voltage V1 and a second voltage V2. Output terminals (e.g., drains) are connected to a voltage output node Nout. A control terminal (e.g., a gate) of the first P-type transistor M1 is connected to the second voltage V2, and a control terminal of the second P-type transistor M2 is connected to the first voltage V1. The voltage output node Nout outputs a maximum voltage between the first voltage V1 and the second voltage V2, i.e., a maximum voltage VM.

In the voltage selector circuit shown in FIG. 1, when the first voltage V1 is greater than a sum of the second voltage V2 and a threshold voltage Vthp of the P-type transistor (i.e., V1>V2+Vthp), the second P-type transistor M2 is turned off and the first P-type transistor M1 is turned on. Accordingly, the maximum output voltage VM is equal to the first voltage V1. When the second voltage V2 is greater than a sum of the first voltage V1 and a threshold voltage Vthp of the P-type transistor (i.e., V2>V1+Vthp), the first P-type transistor M1 is turned off and the second P-type transistor M2 is turned on. Accordingly, the maximum output voltage VM is equal to the second voltage V2.

Under high load current conditions, a connection configuration of the first P-type transistor M1 and the second P-type transistor M2 in FIG. 1 causes the voltage output node Nout to output a voltage of V1−Vthp or V2−Vthp, rather than precisely outputting the first voltage V1 or the second voltage V2. This inaccurate voltage output cannot meet the needs of most electronic applications. Furthermore, when the first voltage V1 and the second voltage V2 are very close, gate-source voltages of both the first P-type transistor M1 and the second P-type transistor M2 are very small. Therefore, unless channel width-to-length ratios (W/L) of the first P-type transistor M1 and the second P-type transistor M2 are specifically selected, both the first P-type transistor M1 and the second P-type transistor M2 will be turned on, and the maximum voltage VM cannot be effectively output.

Therefore, there is a need to solve the above-mentioned problems in the prior art.

### SUMMARY OF DISCLOSURE

An objective of the present disclosure is to provide a voltage selector circuit which can solve a problem of a threshold voltage of a transistor affecting an output voltage. A technical solution is described as follows.

According to one aspect in the embodiment of the present disclosure, the voltage selector circuit is provided, including: a voltage comparator, wherein a first terminal of the voltage comparator is connected to a first voltage, a second terminal of the voltage comparator is connected to a second voltage, and an output terminal of the voltage comparator outputs a comparison signal corresponding to a comparison result between the first voltage and the second voltage; a first inverter, wherein an input terminal of the first inverter is connected to the output terminal of the voltage comparator to receive the comparison signal, and an output terminal of the first inverter outputs a first control signal corresponding to an inversion of the comparison signal; a second inverter, wherein an input terminal of the second inverter is connected to the output terminal of the first inverter, and an output terminal of the second inverter outputs a second control signal corresponding to an inversion of the first control signal; a first N-type transistor, wherein the first N-type transistor is controlled by the first control signal, a control terminal of the first N-type transistor is connected to the output terminal of the first inverter, an input terminal of the first N-type transistor is grounded, and an output terminal of the first N-type transistor is connected to a first node; a second N-type transistor, wherein the second N-type transistor is controlled by the second control signal, a control terminal of the second N-type transistor is connected to the output terminal of the second inverter, an input terminal of the second N-type transistor is grounded, and an output terminal of the second N-type transistor is connected to a second node; a first P-type transistor, wherein a control terminal of the first P-type transistor is connected to the first node, a n input terminal of the first P-type transistor is connected to the first voltage, and an output terminal is connected to a voltage output node; and a second P-type transistor, wherein a control terminal of the second P-type transistor is connected to the second node, an input terminal of the second P-type transistor is connected to the second voltage, and an output terminal is connected to the voltage output node.

A technical solution provided in the embodiment of the present disclosure can have the following beneficial effects.

This application provides a voltage selector circuit, which controls the first P-type transistor and the second P-type transistor to be turned on or off respectively to output the first voltage or the second voltage as a maximum voltage at the voltage output node. Special requirements of threshold voltages of the first P-type transistor and the second P-type transistor are not required in the voltage selector circuit. In case of high load current, the voltage outputted by the voltage output node will not have a voltage drop by the threshold voltage, and the first voltage or the second voltage can be accurately outputted as the maximum voltage. In other embodiments, this application also addresses a problem of output voltage uncertainty and stability when the first voltage is close to the second voltage.

### BRIEF DESCRIPTION OF DRAWINGS

To more clearly illustrate the technical solutions in the embodiments of the disclosure, the drawings used in the description of the embodiments will be briefly introduced below. Obviously, the drawings described below are only some embodiments of the present disclosure. For those skilled in the art, other drawings can be obtained from these drawings without creative effort.

FIG. 1 illustrates a conventional voltage selector circuit.

FIG. 2 illustrates a voltage selector circuit in accordance with an embodiment of the present disclosure.

FIG. 3 illustrates a voltage waveform of the voltage selector circuit in accordance with an embodiment of the present disclosure.

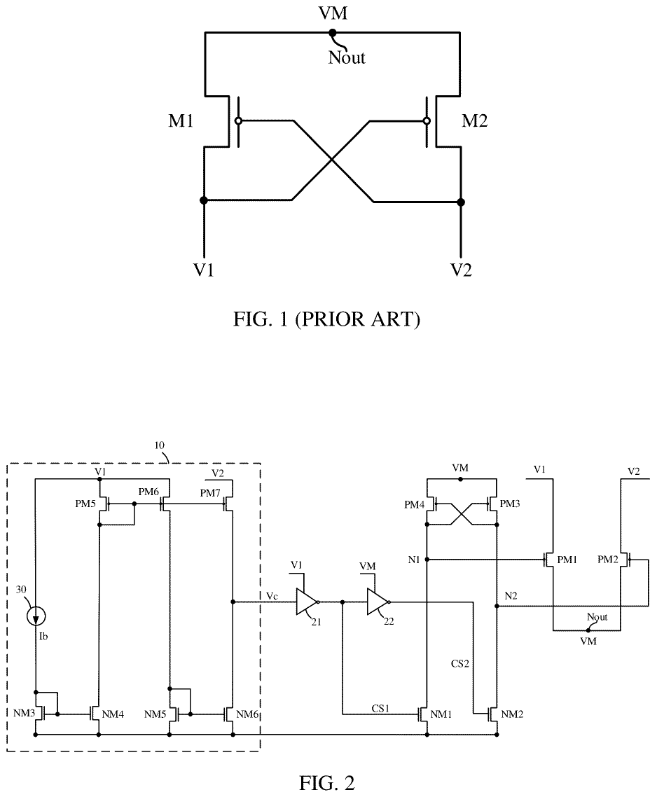

### DETAILED DESCRIPTION OF DISCLOSURE

The technical solutions in the embodiments of the present disclosure will be clearly and completely described below with reference to the accompanying drawings. Obviously, the described embodiments are only some of the embodiments of the present disclosure, and not all of them. All other embodiments obtained by those skilled in the art based on the embodiments of the present disclosure without creative effort are within the scope of protection of the present disclosure.

An embodiment of the present disclosure will be described in detail below with reference to FIG. 2.

FIG. 2 illustrates a voltage selector circuit in accordance with an embodiment of the present disclosure. As shown in FIG. 2, a voltage selector circuit is configured to select a greater of a first voltage V1 and a second voltage V2, i.e., a maximum voltage VM. In an exemplary example, the first voltage V1 can be provided by an adapter, and the second voltage V2 can be provided by a battery. The maximum voltage VM is outputted at a voltage output node Nout. For example, when the first voltage V1 is greater than the second voltage V2 (or the second voltage V2 does not exist), the voltage output node Nout outputs the first voltage V1. When the second voltage V2 is greater than the first voltage V1 (or the first voltage V1 does not exist), the voltage output node Nout outputs the second voltage V2.

As shown in FIG. 2, the voltage selector circuit includes a voltage comparator 10, a first inverter 21, a second inverter 22, a first N-type transistor NM1, a second N-type transistor NM2, a first P-type transistor PM1, and a second P-type transistor PM2. In the present embodiment, the P-type transistors can be P-type metal-oxide-semiconductor field-effect transistor (PMOSFET), and the N-type transistors can be N-type metal-oxide-semiconductor field-effect transistor (NMOSFET). Unless otherwise specified, input terminals of the transistors can be sources, output terminals can be drains, and control terminals can be gates.

As shown in FIG. 2, an input terminal of the first P-type transistor PM1 is connected to the first voltage V1, and an input terminal of the second P-type transistor PM2 is connected to the second voltage V2. Output terminals of the first P-type transistor PM1 and the second P-type transistor PM2 are both connected to the voltage output node Nout. The voltage output node Nout outputs the voltage which is the greater of the first voltage V1 and the second voltage V2, i.e., the maximum voltage VM. That is, when the first P-type transistor PM1 is turned on and the second P-type transistor PM2 is turned off, the voltage output node Nout outputs the first voltage V1 as the maximum voltage VM. When the second P-type transistor PM2 is turned on and the first P-type transistor PM1 is turned off, the voltage output node Nout outputs the second voltage V2 as the maximum voltage VM.

Other elements in the present embodiment will be described in detail below.

A first terminal of the voltage comparator 10 is connected to the first voltage V1, a second terminal of the voltage comparator 10 is connected to the second voltage V2, and an output terminal outputs a comparison signal Vc corresponding to a comparison result between the first voltage V1 and the second voltage V2. For example, when the first voltage V1 is greater than the second voltage V2, the comparison signal Vc is at a low potential. When the second voltage V2 is greater than the first voltage V1, the comparison signal Vc is at a high potential.

An input terminal of the first inverter 21 is connected to the output terminal of the voltage comparator 10 to receive the comparison signal Vc, and an output terminal of the first inverter 21 outputs a first control signal CS1 corresponding to an inversion of the comparison signal Vc. The first control signal CS1 is configured to control the first N-type transistor NM1. An input terminal of the second inverter 22 is connected to the output of the first inverter 21, and an output terminal of the second inverter 22 outputs a second control signal CS2 corresponding to an inversion of the first control signal CS1. The second control signal CS2 is configured to control the second N-type transistor NM2. In the present embodiment, the first inverter 21 is powered by the first voltage V1, and the second inverter 22 is powered by the maximum voltage VM of the voltage output node Nout. Accordingly, when the first voltage V1 is 0, an output voltage of the second inverter 22 can be defined by the voltage V2 (i.e., the maximum voltage). The present disclosure is not limited to this. Other voltages can also be configured to power the first inverter 21 and the second inverter 22.

The first N-type transistor NM1 is controlled by the first control signal CS1. A control terminal of the first N-type transistor NM1 is connected to the output terminal of the first inverter 21, an input terminal is grounded, and an output terminal is connected to a first node N1. The second N-type transistor NM2 is controlled by the second control signal CS2. A control terminal of the second N-type transistor NM2 is connected to the output terminal of the second inverter 22, an input terminal is grounded, and an output terminal is connected to a second node N2. When the first N-type transistor NM1 is turned on, the first node N1 is grounded and a voltage is changed 0. Similarly, when the second N-type transistor NM2 is turned on, the second node N2 is grounded and a voltage is changed 0.

A control terminal of the first P-type transistor PM1 is connected to the first node N1. That is, the turned-on state and the turn-off state of the first P-type transistor PM1 are controlled by a voltage at the first node N1. An input terminal of the first P-type transistor PM1 is connected to the first voltage V1, and an output terminal is connected to the maximum voltage VM. A control terminal of the second P-type transistor PM2 is connected to the second node N2. That is, the turned-on state and the turn-off state of the second P-type transistor PM2 are controlled by a voltage at the second node N2. An input terminal of the second P-type transistor PM2 is connected to the second voltage V2, and an output terminal is connected to the maximum voltage VM.

In the voltage selector circuit in the present embodiment, the maximum voltage VM (i.e., the first voltage V1 or the second voltage V2) outputted by the voltage output node Nout is achieved by controlling to turn on and turn off the first P-type transistor PM1 and the second P-type transistor PM2. The first P-type transistor PM1 and the second P-type transistor PM2 which are turned on and turned off are not directly related to the first voltage V1 and the second voltage V2 but are related to turning on and turning off the first N-type transistor NM1 and the second N-type transistor NM2. Accordingly, no special requirements are needed for a threshold voltage Vthp of each of the first P-type transistor PM1 and the second P-type transistor PM2. Under a high load current, the voltage output by the voltage output node Nout does not have a problem of a voltage drop of the threshold voltage Vthp. Therefore, the voltage output node Nout can accurately output the first voltage V1 or the second voltage V2.

As shown in FIG. 2, the voltage selector circuit in the present embodiment can further include a third P-type transistor PM3 and a fourth P-type transistor PM4. A control terminal of the third P-type transistor PM3 is connected to the first node N1, an input terminal is connected to the maximum voltage VM of the voltage output node Nout, and an output terminal is connected to the second node N2. A control terminal of the fourth P-type transistor PM4 is connected to the second node N2, an input terminal is connected to the voltage VM of the voltage output node Nout, and an output terminal is connected to the first node N1. The third P-type transistor PM3 can be configured to pull up the voltage at the second node N2 to the voltage of the voltage output node Nout when the first N-type transistor NM1 is turned on. The fourth P-type transistor PM4 can be configured to pull up the voltage at the first node N1 to the voltage of the voltage output node Nout when the second N-type transistor NM2 is turned on.

A working principle of the voltage selector circuit in the present embodiment will be described in detail below.

When the first voltage V1 is greater than the second voltage V2 (or the second voltage V2 does not exist and thus V2 is 0), the voltage comparator 10 outputs the comparison signal Vc which is at the low potential. After the comparison signal Vc which is at the low potential passes through the first inverter 21, the first control signal CS1 becomes a high potential and thus the first N-type transistor NM1 is turned on. After the comparison signal Vc which is at the low potential passes through the first inverter 21 and the second inverter 22, the second control signal CS2 becomes a low potential and thus the second N-type transistor NM2 is turned off. When the first N-type transistor NM1 is turned on and the second N-type transistor NM2 is turned off, a potential of the first node N1 is 0. When the third P-type transistor PM3 is turned on, a potential of the second node N2 is pulled up to the maximum voltage VM. The potential of the second node N2 is at the high potential, and thus the fourth P-type transistor PM4 remains off. Since the potential of the first node N1 is 0 and the potential of the second node N2 is at the high potential, the first P-type transistor PM1 is turned on and the second P-type transistor PM2 is turned off. Therefore, the voltage output node Nout outputs the first voltage V1 as the maximum voltage VM. This also avoids a leakage current which may occur when the first voltage V1 is outputted to the voltage output node Nout.

When the second voltage V2 is greater than the first voltage V1 (or the first voltage V1 does not exist and thus V1 is 0), the voltage comparator 10 outputs the comparison signal Vc which is at the high potential. After comparison signal Vc which is at the high potential passes through the first inverter 21, the first control signal CS1 becomes a low potential and the thus first N-type transistor NM1 is turned off. After the comparison signal Vc which is at the high potential passes through the first inverter 21 and the second inverter 22, the second control signal CS2 becomes a high potential and thus the second N-type transistor NM2 is turned on. When the first N-type transistor NM1 is turned off and the second N-type transistor NM2 is turned on, the potential of the second node N2 is 0 and the fourth P-type transistor PM4 is turned on. Accordingly, the potential of the first node N1 is pulled up to the maximum voltage VM. The potential of the first node N1 is at the high potential, and thus the third P-type transistor PM3 remains off. Since the potential of the second node N2 is 0 and the potential of the first node N1 is at the high potential, the second P-type transistor PM2 is turned on and the first P-type transistor PM1 is turned off. Therefore, the voltage output node Nout outputs the second voltage V2 as the maximum voltage VM. This also avoids a leakage current which may occur when the second voltage V2 is outputted to the voltage output node Nout.

In some embodiments, the voltage comparator 10 includes a reference current source 30, a third N-type transistor NM3, a fourth N-type transistor NM4, a fifth N-type transistor NM5, a sixth N-type transistor NM6, a fifth P-type transistor PM5, a sixth P-type transistor PM6, and a seventh P-type transistor PM7. The reference current source 30 generates a reference current Ib which can be driven by only a few nA. The first voltage V1 can be connected from input terminals of the fifth P-type transistor PM5 and the sixth P-type transistor PM6. The second voltage V2 can be connected from an input terminal of the seventh P-type transistor PM7. The comparison signal Vc can be outputted from output terminals of the seventh P-type transistor PM7 and the sixth N-type transistor NM6. Each pair of the third N-type transistor NM3 and the fourth N-type transistor NM4, the fifth N-type transistor NM5 and the sixth N-type transistor NM6, and the fifth P-type transistor PM5 and the sixth P-type transistor PM6 can be regarded as forming a current mirror circuit.

Specifically, an input terminal of the third N-type transistor NM3 is grounded, and an output terminal and a control terminal are connected together and connected to the reference current source 30. An input terminal of the fourth N-type transistor NM4 is grounded, and a control terminal is connected to the control terminal of the third N-type transistor NM3. An input terminal of the fifth P-type transistor PM5 is connected to the first voltage V1, and an output terminal and a control terminal are connected together and connected to an output terminal of the fourth N-type transistor NM4. An input terminal of the sixth P-type transistor PM6 is connected to the first voltage V1, and a control terminal is connected to a control terminal of the fifth P-type transistor PM5.

Furthermore, the input terminal of the seventh P-type transistor PM7 is connected to the second voltage V2, and a control terminal is connected to the control terminals of the fifth P-type transistor PM5 and the sixth P-type transistor PM6. An input terminal of the fifth N-type transistor NM5 is grounded, and an output terminal and control terminal are connected together and connected to an output terminal of the sixth P-type transistor PM6. An input terminal of the sixth N-type transistor NM6 is grounded, a control terminal is connected to a control terminal of the fifth N-type transistor NM5, and an output terminal is connected to an output terminal of the seventh P-type transistor PM7. An output terminal of the sixth N-type transistor NM6 and the output terminal of the seventh P-type transistor PM7 output the comparison signal Vc.

As can be seen from the voltage comparator 10 described above, when the first voltage V1 is greater than 0 and the second voltage V2 is 0, NM3, NM4, NM5, NM6, PM5, PM6, and PM7 are all turned on. At this time, 0 potential of the second voltage V2 is transmitted to the output terminal of voltage comparator 10, and the comparison signal Vc is at the low potential and thus the voltage output node Nout outputs the first voltage V1. When the second voltage V2 is greater than 0 and the first voltage V1 is 0, NM3, NM4, NM5, and NM6 are turned off, and PM5, PM6, and PM7 are turned on. The output comparison signal Vc is at the high potential, and thus the voltage output node Nout outputs the second voltage V2.

When the first voltage V1 is close to and essentially the same as the second voltage V2 (i.e., V1=V2), a current driven by PM7 is less than a current driven by PM6. The voltage outputted by the first inverter 21 powered by the first voltage V1 is close to the first voltage V1, and thus the voltage output node Nout outputs the first voltage V1. Since the first voltage is close to the second voltage, the voltage output node Nout fixed outputs the first voltage V1 as the maximum voltage VM. Accordingly, an uncertainty of sometimes outputting the first voltage V1 and sometimes the second voltage V2 can be avoided, and a situation that the first voltage V1 and the second voltage V2 are outputted simultaneously can be avoided to ensure a stability of the circuit. Certainly, the circuit can be designed appropriately so that, when the first voltage V1 and the second voltage V2 are basically the same, the second voltage V2 is fixed as the maximum voltage VM.

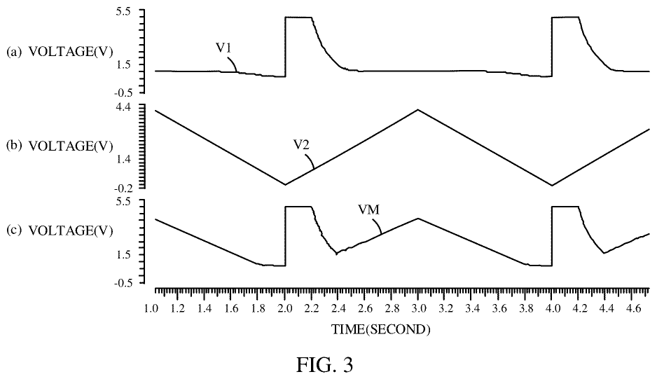

FIG. 3 illustrates a voltage waveform of the voltage selector circuit in accordance with an embodiment of the present disclosure. A part (a) in FIG. 3 illustrates a voltage waveform of the first voltage. A part (b) in FIG. 3 illustrates a voltage waveform of the second voltage. A part (c) in FIG. 3 illustrates a voltage waveform of the maximum voltage. It can be seen in FIG. 3 when the first voltage V1 is greater than the second voltage V2, the maximum voltage VM outputted by the voltage output node Nout is equal to the first voltage V1. When the second voltage V2 is greater than the first voltage V1, the maximum voltage VM outputted by the voltage output node Nout is the second voltage V2.

While the preferred embodiments of the present disclosure have been illustrated and described in detail, various modifications and alterations can be made by persons skilled in this art. The embodiment of the present disclosure is therefore described in an illustrative but not restrictive sense. It is intended that the present disclosure should not be limited to the particular forms as illustrated, and that all modifications and alterations which maintain the spirit and realm of the present disclosure are within the scope as defined in the appended claims.

What is claimed is:

1. A voltage selector circuit, comprising:
a voltage comparator, wherein a first terminal of the voltage comparator is connected to a first voltage, a second terminal of the voltage comparator is connected to a second voltage, and an output terminal of the voltage comparator outputs a comparison signal corresponding to a comparison result between the first voltage and the second voltage;
a first inverter, wherein an input terminal of the first inverter is connected to the output terminal of the voltage comparator to receive the comparison signal, and a n output terminal of the first inverter outputs a first control signal corresponding to an inversion of the comparison signal;
a second inverter, wherein an input terminal of the second inverter is connected to the output terminal of the first inverter, and an output terminal of the second inverter outputs a second control signal corresponding to an inversion of the first control signal;
a first N-type transistor, wherein the first N-type transistor is controlled by the first control signal, a control terminal of the first N-type transistor is connected to the output terminal of the first inverter, an input terminal of the first N-type transistor is grounded, and an output terminal of the first N-type transistor is connected to a first node;
a second N-type transistor, wherein the second N-type transistor is controlled by the second control signal, a control terminal of the second N-type transistor is connected to the output terminal of the second inverter, an input terminal of the second N-type transistor is grounded, and an output terminal of the second N-type transistor is connected to a second node;
a first P-type transistor, wherein a control terminal of the first P-type transistor is connected to the first node, an input terminal of the first P-type transistor is connected to the first voltage, and an output terminal is connected to a voltage output node; and
a second P-type transistor, wherein a control terminal of the second P-type transistor is connected to the second node, an input terminal of the second P-type transistor is connected to the second voltage, and an output terminal is connected to the voltage output node.

2. The voltage selector circuit according to claim 1, wherein when the first voltage is greater than the second voltage or the second voltage does not exist, the first N-type transistor and the first P-type transistor are turned on, the second N-type transistor and the second P-type transistor are turned off, and the voltage output node outputs the first voltage.

3. The voltage selector circuit according to claim 1, wherein when the second voltage is greater than the first voltage or the first voltage does not exist, the second N-type transistor and the second P-type transistor are turned on, the first N-type transistor and the first P-type transistor are turned off, and the voltage output node outputs the second voltage.

4. The voltage selector circuit according to claim 1, further comprising:
a third P-type transistor, wherein a control terminal of the third P-type transistor is connected to the first node, an input terminal of the third P-type transistor is connected to a voltage of the voltage output node, and an output terminal of the third P-type transistor is connected to the second node; and
a fourth P-type transistor, wherein a control terminal of the fourth P-type transistor is connected to the second node, an input terminal of the fourth P-type transistor is connected to the voltage of the voltage output node, and an output terminal of the fourth P-type transistor is connected to the first node.

5. The voltage selector circuit according to claim 4, wherein:
the third P-type transistor is configured to pull up a voltage of the second node to the voltage of the voltage output node when the first N-type transistor is turned on; and
the fourth P-type transistor is configured to pull up a voltage of the first node to the voltage of the voltage output node when the second N-type transistor is turned on.

6. The voltage selector circuit according to claim 1, wherein the first inverter is powered by the first voltage, and the second inverter is powered by a voltage of the voltage output node.

7. The voltage selector circuit according to claim 1, wherein the voltage comparator comprising:
a reference current source;
a third N-type transistor, wherein an input terminal of the third N-type transistor is grounded, an output terminal of the third N-type transistor and a control terminal of the third N-type transistor are connected together and connected to the reference current source;
a fourth N-type transistor, wherein an input terminal of the fourth N-type transistor is grounded, and a control terminal of the fourth N-type transistor is connected to the control terminal of the third N-type transistor;
a fifth P-type transistor, wherein an input terminal of the fifth P-type transistor is connected to the first voltage, an output terminal of the fifth P-type transistor and a control terminal of the fifth P-type transistor are connected together and connected to an output terminal of the fourth N-type transistor; and
a sixth P-type transistor, wherein an input terminal of the sixth P-type transistor is connected to the first voltage, and a control terminal of the sixth P-type transistor is connected the control terminal of the fifth P-type transistor.

8. The voltage selector circuit according to claim 7, wherein the voltage comparator further comprises:
a seventh P-type transistor, wherein an input terminal of the seventh P-type transistor is connected to the second voltage, and a control terminal of the seventh P-type transistor is connected to the control terminals of the fifth P-type transistor and the sixth P-type transistor;
a fifth N-type transistor, wherein an input terminal of the fifth N-type transistor is grounded, and an output terminal of the fifth N-type transistor and a control terminal of the fifth N-type transistor are connected together and connected to an output terminal of the sixth P-type transistor; and
a sixth N-type transistor, wherein an input terminal of the sixth N-type transistor is grounded, a control terminal of the sixth N-type transistor is connected to the control terminal of the fifth N-type transistor, and an output terminal of the sixth N-type transistor is connected to an output terminal of the seventh P-type transistor.

9. The voltage selector circuit according to claim 8, wherein each pair of the third N-type transistor and the fourth N-type transistor, the fifth N-type transistor and the sixth N-type transistor, and the fifth P-type transistor and the sixth P-type transistor is regarded as forming a current mirror circuit.

10. The voltage selector circuit according to claim 8, wherein when the first voltage is close to the second voltage, the voltage output node outputs the first voltage as a maximum voltage.
